(19) United States
(12) Patent Application Publication
(10) Pub. No.: US 2014/0369523 A1
(43) Pub. Date: Dec. 18, 2014

(54) PROCESS FOR IMPROVING AUDIO (API)

(71) Applicant: Lloyd Trammell, Thousand Oaks, CA (US)

(72) Inventor: Lloyd Trammell, Thousand Oaks, CA (US)

(73) Assignee: Max Sound Corporation, La Jolla, CA (US)

(21) Appl. No.: 14/182,217

(22) Filed: Feb. 17, 2014

Related U.S. Application Data
(60) Provisional application No. 61/765,634, filed on Feb. 15, 2013.

(51) Int. Cl. H03G 5/16

(52) U.S. Cl. CPC H03G 5/165
USPC 381/103

(57) ABSTRACT

A computer implemented method for improving audio, comprising processing audio with a combination of wave adjustment tool WAT and a collection of preset settings for adjusting specific harmonic content to specific genres of music. The preset is selected from the group comprising different genres (styles or types) of music; auto-preset; and generic preset. The auto preset value is determined by the metadata which is commonly included in an audio file. In the event there is no match between the preset genre names and the one in the metadata, then the selected preset will be “Generic.” This particular genre preset is designed for optimal sound across many genres, making it generic. The wave adjustment tool (WAT) allows for low, mid, and hi tone controls. The process is carried out by installing software in an existing audio path immediately after initial input and prior to output. A host device provides for a buffer to allow for processing of audio. A program placed in libraries that work together is used improve audio quality.

### CROSS-REFERENCE TO RELATED PATENT APPLICATIONS

Embodiments of the present invention relate to U.S. Provisional Application Ser. No. 61/765,634, filed Feb. 15, 2013, entitled “PROCESS FOR IMPROVING AUDIO”, the contents of which are incorporated by reference herein and which is a basis for a claim of priority.

### BACKGROUND OF THE INVENTION

In sound recording and reproduction, equalization is the process commonly used to alter the frequency response of an audio system using linear filters. Most hi-fi equipment uses relatively simple filters to make bass and treble adjustments. Graphic and parametric equalizers have much more flexibility in tailoring the frequency content of an audio signal. An equalizer is the circuit or equipment used to achieve equalization. Since equalizers adjust the amplitude of audio signals at particular frequencies, they are, in other words, frequency-specific volume knobs.¹ ¹ http://en.wikipedia.org/wiki/Equalization_(audio)

Equalizers are used in recording studios, broadcast studios, and live sound reinforcement to correct the response of microphones, instrument pick-ups, loudspeakers, and hall acoustics. Equalization may also be used to eliminate unwanted sounds, make certain instruments or voices more prominent, enhance particular aspects of an instrument's tone, or combat feedback (howling) in a public address system. Equalizers are also used in music production to adjust the timbre of individual instruments by adjusting their frequency content and to fit individual instruments within the overall frequency spectrum of the mix. ² ² See, n.1, above

The most common equalizers in music production are parametric, semi-parametric, graphic, peak, and program equalizers. Graphic equalizers are often included in consumer audio equipment and software which plays music on home computers. Parametric equalizers require more expertise than graphic equalizers, and they can provide more specific compensation or alteration around a chosen frequency. This may be used in order to remove (or to create) a resonance, for instance. ³ ³ See, n.1, above

Tone control is a type of equalization used to make specific pitches or “frequencies” in an audio signal softer or louder. A tone control circuit is an electronic circuit that consists of a network of filters which modify the signal before it is fed to speakers, headphones or recording devices by way of an amplifier.⁴ ⁴ http://en.wikipedia.org/wiki/Tone_control_circuit

As audio has become more data compressed (MP3, AAC, FLAG, etc.), the quality has greatly suffered. There is therefore a need in the art to improve quality of a sound while keeping costs low.

### SUMMARY OF THE INVENTION

API is a low requirement, but high quality method and system for improving an original input audio. Advantageously, when a program is turned into an API, the core technology is not exposed. There are only places to connect and control the API available to be used or seen.

A manufacturer can implement the API audio technology into its own devices with ease. The API would be compiled for whatever format is needed, including custom ones. Using the API will greatly increase both the dynamic and frequency ranges of the audio passed through it.

Exemplary uses of API include automotive, consumer electronics, and entertainment audio systems. API is dynamic, not static, process for greater precision and quality than ever before available to these types of uses.

The inventive API of is a computer implemented method for improving audio, which includes processing audio with a combination of the wave adjustment tool that is the subject of co-pending U.S. patent application No. ______, filed on ______, entitled WAVE ADJUSTMENT TOOL (WAT); and a collection of preset settings for adjusting specific harmonic content to a specific genres of music.

In one embodiment the preset settings is selected from the following criteria a) different genres (styles or types) of music; b) auto-preset, and c) a generic preset. Preferably, the auto preset value is determined by the metadata which is commonly included in an audio file. In one embodiment, where there is no match between the preset genre names and the one in the metadata, the selected preset will be “Generic.” This particular genre preset is designed for optimal sound across many genres, making it generic.

### BRIEF DESCRIPTION OF THE DRAWINGS

FIG. 1 is a signal flow chart showing the Wave Adjustment Tool module according to an embodiment of the present invention.

FIG. 2 is a signal flow chart showing API processing of PCM digital audio for use on a DSP chip.

### DETAILED DESCRIPTION OF THE PREFERRED EMBODIMENT(S)

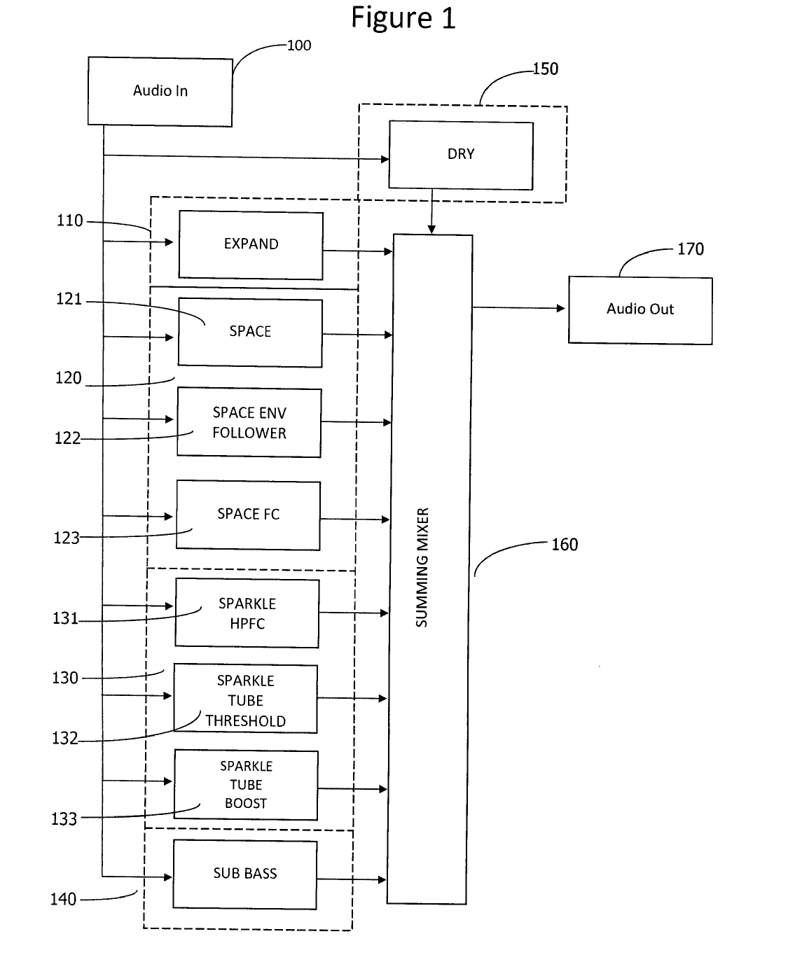

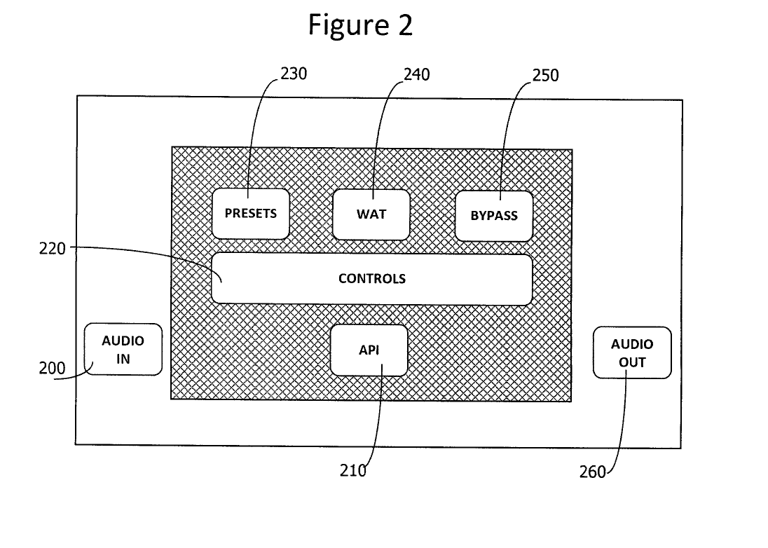

The details of the present invention will now be described with reference to the drawings in FIGS. 1 and 2. Audio input 100 is stored in a buffer. There are specific controls that are available to an end user. These controls 220 allow a user to adjust presets 230, WAT 240, or bypass 250 the process.

There can be multiple types of presets available. Each preset 230 will select a specific genre of music. Another preset can be auto-preset that is selected by genre in metadata. Yet another preset is a single generic preset that covers all music. Preset 230 consists of the modules below, with explanation of same. Advantageously, controls 220 are not exposed in the API 210, only a name which represents the settings for that particular setting (preset). Explanation of the functions are provided below.

Explaining WAT 240 (FIG. 2) for one exemplary embodiment, with reference to FIG. 1, EXPAND 110 is a 4 pole digital low pass filter with an envelope follower for dynamic offset (fixed envelope follower). This allows the output of the filter to be dynamically controlled so that the output level is equal to whatever the input is to this filter section. For e.g., if the level at the input is −6 dB, then the output will match that. Moreover, whenever there is a change at the input, the same change will occur at the output regardless of either positive or negative amounts. The frequency for this filter is, e.g., 20 to 20 k hertz, which corresponds to a full range. The purpose of EXPAND 110 is to “warm up” or provide a fuller sound as audio 100 passes through it. The original sound 100 passes through, and is added to the effected sound for its output. As the input amount 100 varies, so does the phase of this section. This applies to all filters used in this software application. Preferably all filters are of the Butterworth type.

Next, we discuss SPACE 120. In FIG. 1, SPACE 120 refers to the block of three modules identified by reference numerals 121, 122 and 123. The first module SPACE 121—which follows EXPAND 110 envelope follower, sets the final level of this module. This is the effected signal only, without the original. SPACE ENV FOLLOWER 122 tracks the input amount and forces the output level of this section to match. SPACE FC 123 sets the center frequency of the 4 pole digital high pass filter used in this section. This filter also changes phase as does EXPAND 110.

SPACE blocks 120 are followed by the SPARKLE 130 blocks. Like SPACE 120, there are several components to SPARKLE. SPARKLE HPFC 131 is a 2 pole high pass filter with a preboost which sets the lower frequency limit of this filter. Anything above this setting passes through the filter while anything below is discarded or stopped from passing. SPARKLE TUBE THRESH 132 sets the lower level at which the tube simulator begins working. As the input increases, so does the amount of the tube sound. The tube sound adds harmonics, compression and a slight bit of distortion to the input audio 100. This amount increases slightly as the input level increases. SPARKLE TUBE BOOST 133 sets the final level of the output of this module. This is the effected signal only, without the original.

Next, the SUB BASS 140 module is discussed. This module takes the input signal and uses a low pass filter to set the upper frequency limit to about 100 Hz. An octave divider occurs in the software that changes the input signal to lower by an octave (12 semi tones) and output to the only control in the interface, which is the level or the final amount. This is the effected signal only, without the original.

All of the above modules 110 to 140 are directed into SUMMING MIXER 160 which combines the audio. The levels going into the summing mixer 160 are controlled by the various outputs of the modules listed above. As they all combine with the original signal 100 fed through the DRY 150 module there is interaction in phase, time and frequencies that occur dynamically. These changes all combine to create a very pleasing audio experience for the listener in the form of “enhanced” audio content. For example, a change in a single module can have a great affect on what happens in relation to the other modules final sound or the final harmonic output of the entire software application.

Referring now to FIG. 2, according to an embodiment, input audio 200 can also be processed by Wave Adjustment Tool (WAT) 240. WAT 240 allows for low, mid, and hi tone controls and, as noted above, is subject to a separate patent application.

Bypass 250 allows user to turn API 210 on or off. After API 210, the audio continues in the audio path and can be stored in a device or output as audio 260. By using Bypass 250 user can compare the treated versus the untreated audio.

API 210 provides superior quality audio from compressed formats such as MP3, AAC, etc. API 210 allows for selection of specific presets and fine-tuning of audio within three frequency ranges with the Wave Adjustment Tool 240. A user GUI can be graphically built to the customer preferences, within the limits of the device the API 210 is installed in. Additional custom presets can be created and inserted into the API 210.

API 210 includes a single shared library compiled for the target platform and delivered as a binary. The library is written in C++ and delivered with headers that can be used in either C or C++. In an exemplary implementation, API 210 is inserted in the audio signal 200 path immediately prior to the output. The host provides a single interleaved buffer or two mono buffers for processing. The processed buffer(s) is returned to the host for further processing.

Buffers can be provided in linear PCM format and can be 8, 16, 24, or 32 bits. Internally, the API processor 210 converts the samples to floating point prior to processing. The samples are then converted back to the input format. The process supports any sample rate; however changing from one sample rate to another requires creating a new instance of the object.

A buffer is submitted for processing, and remains active until a different preset is selected. Wave Adjustment Tool 240 equalization (low, medium, and high) is also available. Changes to equalization can be made at the beginning of processing a new buffer.

The WAT 240 affects specific frequency ranges. At this time there are three control ranges (low, mid, high) that operate in both negative and positive amounts. These amounts are determined by the program. In all three controls, the frequencies, the widths, and the amounts are changed as the sliders move up and down (positive or negative) directions.

Control module is shown by reference numeral 220. The control choices available to the manufacturer/end user on an API configured device can be, for example, any or all of the following:

1. Preset select
2. Low amount +/−
3. Mid amount +/−
4. High amount +/−
5. WAT Zero (Sets the WAT tone controls to zero or null)

### 5. Bypass

The API 210 is very basic for installation and/or use. The host application creates an instance of the object, passing in a default buffer size and sample rate. The host then simply calls the process routine as audio buffers become available.

After the API 210 is properly implemented, the manufacturer/end user can expect much more harmonic content and greater dynamic range than without the API. Almost like lifting a blanket off of your speakers. Another advantage is that the manufacturer can use less efficient, and less costing, components to achieve much better sound.

What is claimed is:

1. A computer implemented method for improving audio, comprising processing audio with a combination of:
wave adjustment tool WAT;
a collection of preset settings for adjusting specific harmonic content to specific genres of music.

2. The method of embodiment 1, wherein the preset is selected from the group comprising:
different genres (styles or types) of music;
auto-preset; and
generic preset.

3. The method of claim 2 wherein the auto preset value is determined by the metadata which is commonly included in an audio file.

4. The method of claim 3 wherein if there is no match between the preset genre names and the one in the metadata, then the selected preset will be “Generic.” This particular genre preset is designed for optimal sound across many genres, making it generic.

5. The method of embodiment 1, wherein the wave adjustment tool (WAT) allows for low, mid, and hi tone controls.

6. The method of embodiment 1, wherein the process is carried out by installing software in an existing audio path immediately after initial input and prior to output.

7. The method of embodiment 1, wherein a host device provides for a buffer to allow for processing of audio.

8. The method of embodiment 1, wherein a program placed in libraries that work together is used improve audio quality.
